(19) United States
(12) Patent Application Publication
(10) Pub. No.: US 2026/0271673 A1
(43) Pub. Date: Sep. 10, 2026

(54) WAFER HOLDER

(71) Applicant: EVATEC AG, Trübbach (CH)

(72) Inventors: Hubert BREUSS, Rankweil (AT); David Meinrad WALSER, Mels (CH); Alexander LUTZ, Buchs SG (CH); Valerio FAZIO, Rheineck (CH); Sebastian BECK, Meiningen (AT); Stefan RHYNER, Buchs (CH)

(21) Appl. No.: 19/489,303

(22) PCT Filed: Jun. 6, 2024
(86) PCT No.: PCT/EP2024/065528

§ 371 Date: Dec. 2, 2025

(30) Foreign Application Priority Data
Jun. 30, 2023 (CH) CH000707/2023

(51) Int. Cl. H10P 72/76; F16J 15/40

(52) U.S. Cl. CPC H10P 72/7626; F16J 15/40; H10P 72/7606; H10P 72/7612

(57) ABSTRACT

A wafer holder and treatment arrangement mountable to a vacuum wafer treatment chamber, comprising
a base arrangement with an annular surface;
a wafer carrier plate mounted centrally on a drive shaft centered with respect to a center of said annular surface, said drive shaft with the carrier plate rotatable about a rotational axis Z through said center of said annular surface with respect to and supported by said base arrangement;
a dynamic vacuum seal connected to the drive shaft;
an axial distance setting device mounted lockable to the drive shaft and rotatably supported by an element of said base arrangement or in or on the floor of a treatment chamber setting a critical distance d_{c};
wherein said d_{c} is a distance in a direction parallel to axis Z between said annular surface and one surface of said carrier plate facing the base arrangement and in parallel with said annular surface.

### TECHNICAL FIELD OF THE INVENTION

The current invention relates to a wafer holder and treatment arrangement, to a vacuum treatment apparatus and to a method to set a nominal value of a critical distance d_{c} between a base arrangement and a rotatable metal circular wafer carrier plate. The invention further relates to a rotary drive shaft and vacuum feedthrough.

### DESCRIPTION OF THE RELATED ART

Different embodiments of a wafer holder and treatment arrangement for high temperature applications are known from the prior art, e.g. from WO2013/030190 of the present applicant. Such a wafer holder and treatment arrangement, also called chuck in the following, works fine as long as manufacturing tolerances in the range of some tenth of a millimeter for the relevant assembled chuck elements do not influence certain systemic properties of a chuck. However, when certain properties, as an example the capacity of an RF-driven and capacitively coupled chuck depend on such small tolerances resulting from a multitude of assembled elements, large scattering of the desired property may result. Therefore, the present invention discloses a chuck where a tolerance deviation from a geometrical nominal value critical for certain properties of the assembled chuck can be adjusted comfortably.

### Definitions

An annular surface as used in the present description includes annular and disclike surfaces with a central hole as well as respective annular and disclike surfaces interrupted by recesses, which may be radially elongated or arranged in a radial symmetry along a radius within the annular surface, to accommodate functional elements like fastening means, different types of wafer supports to lift a wafer, media or measuring through holes and the like;

A respective definition applies also to the term circumferential plane, rim, surface, boarder, shield or nose comprising also respectively interrupted structures.

A respective definition applies also to the term circular wafer carrier plate which may include disc like carrier plates without or with a central hole, e.g. a central back-gas inlet, as well as respective circular plates interrupted by recesses as exemplarily mentioned above.

A dynamic vacuum seal, also named dynamic seal or dynamic gasket in the following, is a vacuum seal for sealing a feedthrough, especially a rotary feedthrough of a respectively moving or moved element that is partly in vacuum and partly under atmosphere. Examples are dynamic seals to seal rotating shafts or dynamic gaskets to seal linear moving parts like linear shutters.

An essentially plane surface in the sense of the present description is a plane surface which may also comprise electrical connectors, a viewing or measuring window, recesses or sockets to hold certain elements in place in, on or above the plane surface.

### SUMMARY OF THE INVENTION

It is a task of the current invention to provide a chuck, e.g. a rotating chuck, which can be mounted easily and in high precision. It is a further task of the present invention to provide an assembled chuck allowing a measurement of a certain geometric parameter and adjusting the parameter, when necessary, by a predefined adjustment operation to set the parameter to a nominal value. It is a further task to set certain properties of the chuck by the as mentioned adjustment operation. As an example, it is a task of the present invention to provide means to set the capacity of an RF-chuck easily and precisely by adjusting the distance between a base arrangement and an electrically isolated wafer carrier plate, respectively by adjusting the distance between respective capacitance determining surfaces of the base arrangement and the wafer carrier plate. It is a further task of the present invention to provide means to position rotating parts in a vacuum treatment chamber with high precision towards the chamber or towards certain static installations within the treatment chamber.

According to the present invention, at least one of these tasks is solved by a wafer holder and treatment arrangement according to claim 1, by a vacuum treatment apparatus according to claim 19, by a method according to claim 20, and a rotary drive shaft and vacuum feedthrough according to claim 22.

At least some of these tasks are solved by an inventive embodiment of a wafer holder and treatment arrangement also known and named as a chuck in the following, to be mounted to a vacuum wafer treatment chamber, the wafer holder and treatment arrangement (the chuck) comprising:
a base arrangement with an annular surface;
a metal circular wafer carrier plate mounted centrally on a drive shaft centered with respect to a center of said annular surface, said drive shaft with the carrier plate being rotatable about a geometric axis Z through said center of said annular surface with respect to and supported by said base arrangement;
a dynamic vacuum seal configuration operatively connected to the drive shaft;
an axial distance setting device mounted lockable to the drive shaft and designed to be rotatably supported by an element of said base arrangement, e.g., an inner rim or nose of a bottom plate, a part of the dynamic vacuum seal configuration, or in or on the floor of the treatment chamber, e.g., on a circular surface round a through hole of the floor or an inner rim or nose round the through hole, to set a critical distance d_{c}; to give the distance setting device better gliding properties, the device as a whole or the supported contact areas of the device may made of a bearing metal or be provided, e.g. coated, with a dry gliding layer;
wherein said critical distance dc is defined as a distance in a direction parallel to axis Z between said annular surface of said base arrangement and one surface of said metallic circular wafer carrier plate facing the base arrangement and being in parallel with said annular surface; the one surface of the wafer carrier plate may comprise a further annular surface area overlapping with the annular surface in a Z-projection; said annular surface and said one surface of said wafer carrier plate may be plane surfaces with reference to horizontal or may be oblique to it.

The base arrangement of the wafer holder and treatment arrangement may further comprise an extended, essentially plane surface bordered by a protruding circumferential rim forming said annular surface in a direction towards the one surface of said wafer carrier plate.

The rim may further comprises a circumferential inner rim surface protruding from and bordering the essentially plane surface, whereat a surface of said wafer carrier plate facing said base arrangement, said extended, essentially plane surface and said inner rim surface commonly define a heater compartment, the heater compartment comprising a multitude of heater lamp tubes arranged in said heater compartment along said extended, essentially plane surface and along said one surface of said metal circular wafer carrier plate, and directed to said one surface of said metal circular wafer carrier plate, and mounted to said base arrangement.

The wafer holder and treatment arrangement may further comprise a wafer retaining arrangement to be operationally coupled to said metal circular wafer carrier plate.

The wafer holder and treatment arrangement may comprise at least three wafer supports mounted extendable and retractable out of or into said annular surface, whereby said annular surface can be divided into at least three separate surfaces, e.g. end surfaces of the rim. Thereby also at least an upper part of the inner rim surface with respect to a lower bottom can be divided into exemplary three separate end surfaces of the rim. The wafer supports may be pin-like, or with a radially oriented elongated effector head, which may comprise steps and/or sloped areas and support areas on or adjacent to a wafer support surface of the effector head to center the wafer during transfer and hold it in place during processing. Said metal circular wafer carrier plate will in this case be provided with respective slits to allow the wafer supports to pass and lift or lower the wafer from or on the wafer carrier plate. Only when the wafer supports are retracted in the annular surface or if they are fully extended the wafer carrier plate is allowed to rotate, e.g., to be heated together with the wafer or alone. Therefore wafer supports may be arranged essentially intruding with the wafer support surface of the effector only into the diameter of the wafer carrying surface of the wafer carrier plate, whereas rods to which the effector heads are mounted to be moved vertically are placed outside a projection of the rotating carrier plate. Means for aligning the slits with the wafer supports may be provided with the wafer holder and treatment arrangement.

The wafer holder and treatment arrangement may further comprise a bottom plate comprising said annular surface and said dynamic vacuum seal configuration encompassing in operation a sealing surface of the drive shaft of the wafer carrier plate, whereat the distance setting device is operationally supported rotatably by an element of said bottom plate, e.g., an inner rim or nose of said bottom plate, or an element of said dynamic vacuum seal configuration, e.g., the housing of a dynamic seal configuration, which can exemplarily be a ferrofluidic seal configuration. The bottom plate can be made from one piece with the rim or separately.

In a further inventive embodiment the distance setting device of the chuck may comprise a longitudinally slotted or divided hollow body, i.e. slotted or divided in parallel to a central axis Z′ of the hollow body, made from a bearing alloy or at least provided, e.g. coated, with a dry gliding layer on a gliding surface on a face area of the hollow body. By providing a slot the elasticity of the metallic body can be used to widen the slot and thereby widen the inner diameter of the distance setting device after it has been put over the shaft during a mounting operation, and move the distance setting device fast and easily to a preliminary shaft position in a middle region of the fine thread where it can be left to snap back and clamp on the shaft. Thereafter a precis position can be set whit the help of the fine thread and a locking mechanism as will be described later. Alternatively, the distance setting device can be also designed as a two-part hollow body divided by a continuous slot into two halves of a nut like body and respectively mounted to the shaft by two locking mechanisms, which can be of the same type or differently designed. The hollow body may have the shape of a continuous slotted or divided nut, having the gliding surface on a lower face area when mounted in working position to the drive shaft. The slotted hollow body having an internal fine thread to interact with a shaft fine thread on an outer diameter of said drive shaft, and a locking mechanism to connect the slotted body and lock or dismantle it on or from said fine thread of the drive shaft. Details of the locking mechanism to lock a final position of the distance setting device on the drive shaft are described below. The bearing alloy may be a bronze, a tin or a lead bronze or respective white metal bearings, which can be also provided as a coating. Other dry gliding coatings would be hard carbon or diamond like carbon (DLC) coatings like a-C or a-C:H, ta-C or ta-C:H, a-C:Me or a-C:H:Me, or a-C:H:X with X for Si, O, N, F or B. Such coatings can be provided at least on the supported contact areas, e.g., a part or the whole circumferential surface area on the front face of the distance setting device.

The locking mechanism may comprise at least one threaded connection, e.g. a screw connection, between the two sides of the hollow body adjacent to the slot, i.e. the slot sides, and outside the diameter or a projection of the diameter of the fine thread and parallel to a tangent of the fine thread diameter.

In the slotted or divided hollow body a spring and snap-in ball assembly can be provided in a radial bore of the body with an opening towards axis Z′, to interact with respectively elongated, axially directed groves provided in an outer diameter of said drive shaft, e.g. below or above the fine thread in an axially direction. The interaction can be performed by turning the slotted hollow body on the driveshaft whereby pressing/releasing a part of the spring loaded ball through the opening into/out of the groves to snap-in/out is enforced by the screwing operation. When the slotted hollow body is on the drive shaft and the spring loaded ball snapped in at a new position referring to the nominal distance to be set, the position can be locked by the screw connection. A fine thread which could be used on a typical shaft diameter of 20 to 50 mm provides during one full 360° turn of the thread an axial counter movement of the slotted body connected by the fine thread to achieve a respectively finetuned setting. Providing 10 elongated, axially directed groves equidistant on an outer diameter of the drive shaft would therewith suffice to provide a setting of 0.1 mm per step, i.e., moving from one snapped in position to the next. The length of the groves hereby defines the height of the axial precision adjustment possible.

In a further inventive embodiment said metal circular wafer carrier plate of the chuck can be electrically isolated from said base arrangement and designed to be electrically connected or, preferably capacitively coupled to an electric biasing source, e.g. through the base arrangement. Therefore, an electric isolator may be arranged between said drive shaft and said carrier plate, and a peripheral surface area of said surface facing the base arrangement, which can be a further annual surface area overlapping with the annular surface area of the base arrangement in an axial projection, can be arranged in parallel with at least a part of said annular surface of the base arrangement, said peripheral surface area and said annular surface both forming together an essentially circumferential planar capacitor with a defined capacitive gap of said critical distance d_{c}.

In a further embodiment, the wafer holder and treatment arrangement may comprise a gas outlet- and dispensing-arrangement through and along a wafer carrying surface which is the other surface of the wafer carrier plate. The gas outlet- and dispensing-arrangement can be in operational/fluid connection with a central gas inlet of the drive shaft.

In a further embodiment of the invention said carrier plate of said chuck may comprise a double-walled sleeve-cup mounted with its outer cup-wall on or in a center of said surface facing the base arrangement and with its inner cup-wall electrically isolated on a head of the drive shaft.

Therewith the sleeve-cup forming a part of the drive head may comprise a central gas passthrough from a central gas inlet of the drive shaft towards said gas outlet- and dispensing-arrangement. The passthrough may comprise or form an opening towards the interspace between the double walls, to set the double wall under vacuum and thereby form a heat barrier during vacuum treatment processes to isolate the shaft from the thermal load of the heater compartment.

Said head of the drive shaft may comprise two parallel flanges overlapping in a Z-projection and each directed to a different end of the drive shaft, with at least one isolator mounted on each flange and fixing elements to mount the sleeve-cup on the drive shaft. As an example the fixing elements may comprise clamps or screws to mount the head and isolator arrangement in the inner bottom of the sleeve-cup. Additional isolating bushings may be provided in the screw holes of the head as well as a metallic mounting ring or respective washers to avoid mechanic overload of ceramic isolators when mounted. Such a configuration can be also used without the double-walled sleeve-cup to mount the drive shaft directly to the wafer carrier plate.

To form a further reflector and heat barrier to protect the drive shaft from the heat of said lamps in said heater compartment, an inner heat protective wall circumferential to the drive shaft and/or the sleeve-cup may be provided.

In a further embodiment the wafer holder and treatment arrangement or a respective treatment chamber or treatment system encompassing said treatment arrangement may comprise electric or a respective process power control unit controlling power to said multitude of heater lamp tubes and conceived to operate said multitude of heater lamp tubes so as to establish along the wafer carrying surface of said metal circular wafer carrier plate, opposite said one surface thereof, a predetermined temperature, averaged over said other surface.

In one embodiment of the invention, which may be combined with any of the previously and subsequently addressed embodiments unless in contradiction, the multitude of heater lamp tubes consists of a multitude of equal heater lamp tubes, which are mounted in the heater compartment equally oriented with respect to radial direction from the centre to the circular rim surface. Thereby, in a further embodiment, the length extent direction of the heater lamp tube is angularly offset with respect to the radial direction from the centre of the essentially plane surface towards the protruding circular rim surface.

In a further embodiment, which may be combined with any of the previously and subsequently addressed embodiments unless in contradiction, the position of at least a part of the heater lamp tubes in the heater compartment may be adjusted, so as to optimize temperature distribution along a wafer disposed on the metal circular wafer carrier plate and rotated therewith and thus with respect to the heater lamp tubes.

In one further embodiment, which may be combined with any of the already and subsequently addressed embodiments, unless in contradiction, the heater lamp tubes have a thickness extent which fills the heater compartment between the extended essentially plane surface and the one surface of the metal circular wafer carrier plate without contacting these surfaces. In other words, the heater compartment thickness is practically filled by the thickness extent of the heater lamp tubes.

More specifically, the wafer holder and temperature conditioning arrangement of the present invention and in specific embodiments, which may be combined with any of the embodiments addressed above unless in contradiction, the wafer carrier plate is conceived for one of.
a 100 mm diameter wafer, whereby the multitude of heater lamp tubes consists of three 540W IR emitter lamp tubes;
a 150 mm diameter wafer, whereby the addressed multitude consists of three 540W IR emitter lamp tubes;
a 200 mm diameter wafer, whereby the multitude as addressed, consists of three 540W IR emitter lamp tubes;

In one embodiment which may be combined with any of the already and the subsequently addressed embodiments, unless in contradiction, there is provided a fluid line arrangement in the base arrangement conceived to flow a liquid therein, e.g., a cooling liquid to cool down a processed wafer whenever necessary.

In a further embodiment of the invention said wafer retaining arrangement can be a weight-ring dimensioned so, as to reside on the periphery of a wafer. Depending on the process needs said weight-ring may be electrically connected to an electric bias source or preferably may be coupled capacitively to the metal circular wafer carrier plate by an area in parallel and facing an area beyond a wafer support area of the wafer carrier plate and/or may be coupled capacitively in an inner cylindric area concentric with an area forming at least a part of an outer essentially cylindrical surface of the wafer carrier plate. Alternatively, and/or in addition the weight-ring may be coupled capacitively by an area in parallel and facing a respectively plane or cylindrical area of the base arrangement beyond said annular surface of the base arrangement.

The invention is further directed to a vacuum treatment apparatus comprising a wafer holder and treatment arrangement as described in detail above, the apparatus may comprise a vacuum pumping arrangement and at least one target and a target shutter to separate said target from a process space between said target and said wafer carrying surface. In case of multiple targets, e.g. two or three targets mounted in a dome or calotte structure pivotable or rotatable, common or separate target shutter(s) can be used. Optionally one, e.g. preferably linear process shutter can be used to separate all targets and the target shutter(s), as far as provided, at once from said process space.

The invention is further directed to a method of setting a nominal value of a critical distance d_{c} between a base arrangement of a chuck and a rotatable metal circular wafer carrier plate of the chuck, e.g., to perform a vacuum heat treatment and/or a vacuum deposition process with the wafer, whereby an axial distance setting device being designed to amend respective distance values in predefined differential, e.g. equidistant steps is used, whereat
said distance d_{c} is defined as a distance, which can be the shortest distance, in a direction parallel to axis Z between said base arrangement, e.g., an annular surface of the base arrangement, and one surface, e.g., a further annular surface area of said metallic circular wafer carrier plate facing the base arrangement and/or a corresponding radially extended surface of a component facing the base arrangement, and attached to the carrier plate to rotate therewith (as an example, such a component could be electrically connected to the carrier plate, e.g., a metallic weight-ring), whereat
said base arrangement comprises at least an essentially annular surface
said wafer carrier plate being centrally mounted on a drive shaft being rotatable about a geometric axis through said center of said annular surface with respect to said base arrangement,
said distance setting device being mounted lockable to the drive shaft and designed to be supported rotatably by an element of said base arrangement, by a housing of a dynamic vacuum seal, or in or on the bottom of a treatment chamber;
   whereat said setting comprises at least the following steps in the specified sequence:
determining an average distance d_{cA} by measuring distance d_{c} several times in different positions of the wafer carrier plate in relation to the base arrangement, calculating the mean value d_{cA} thereof, comparing it to a nominal distance d_{cN}, and in case of a difference surmounting a distance value of at least one differential step as predefined:
demounting said drive shaft together with said wafer carrier plate and said distance setting device from the base arrangement and eventually from the drive as far as the drive shaft has been coupled for positioning the wafer carrier plate; demounting from the base arrangement will usually take place, when the base arrangement has been mounted on or in the floor of the vacuum treatment chamber;
adjusting said average distance d_{cA} in differential steps as predefined by said distance setting device to the nominal distance d_{cN} in the demounted state and locking the distance setting device on the drive shaft,
mounting said drive shaft together with said wafer carrier plate and said distance setting device to the base arrangement and the drive.

For said determining of an average distance d_{cA} a weight-ring or a dummy weight, e.g., in the form of a ring or a cylinder, can be set on the circular wafer carrier plate, e.g. to press a dynamic vacuum sealing into its load position against the back-lash of a ferrofluidic seal configuration.

The drive shaft together with the wafer carrier plate and the distance setting device, forms a rotary module, which can be easily mounted and demounted from the base module as a single unit when pre-assembled. Additional elements of the rotary module which would be pre-assembled as far as provided could be a sleeve-cup, isolators, fixing elements, and the like as mentioned above.

The invention is further directed to a rotary drive shaft and vacuum feedthrough having a vertical rotational axis Z, a shaft head and a shaft foot, the drive shaft comprising
mounting means designed to mount a carrier plate centrally on the head of the drive shaft;
a power coupling area at or near the foot of the drive shaft;
an elongated sealing surface round a diameter of the drive shaft allowing a rotational and an axial linear movement of the drive shaft for mounting the drive shaft into a dynamic vacuum seal;
an axial distance setting device encompassing a thread diameter of the drive shaft and mounted movable and lockable in an axial parallel direction to axis Z to the drive shaft, the distance setting device having a gliding surface on a lower face to support the distance setting device and the drive shaft when locked.

Thereby the distance setting device may have an internal thread in engagement with an external thread in the area of the thread diameter of the shaft. The distance setting device may further comprise a locking mechanism to lock a movement of the distance setting device on the drive shaft.

The rotary drive shaft may further comprise a scaled diameter next to the threaded diameter, the scaled diameter having a circumferential readable scale with axially directed elongated markings, and the distance setting device may encompass also a scaled diameter and scale scanning means, e.g. mechanically scale scanning means, to set the distance setting device stepwise from one marking to the next marking.

The features of the above-mentioned embodiments of the devices/processes can be used in any combination, unless they contradict each other.

### BRIEF DESCRIPTION OF THE DRAWINGS

Embodiments of the current invention are described in more detail in the following with reference to the figures. These are for illustrative purposes only and are not to be construed as limiting. It shows

FIG. 1 a schematic drawing of a chuck arrangement,

FIG. 2 a schematic drawing of a rotating capacitively coupled chuck arrangement,

FIG. 3 a schematic drawing of a respective hot chuck arrangement,

FIG. 4 a cross section of a capacitively coupled hot chuck arrangement,

FIG. 5 a top view of a base arrangement,

FIG. 6 a capacitive scatter diagram of a chuck of the prior art,

FIG. 7 a schematic drawing of a vacuum treatment apparatus,

FIG. 8 a top view of an inventive base arrangement

FIG. 9 a cross section of a capacitively coupled hot chuck arrangement,

FIG. 10 a capacitive scatter diagram of an inventive chuck,

FIG. 11A a 3D-view of a slotted hollow body made from a bearing alloy,

FIG. 11B a 3D-view of a divided hollow body,

FIG. 12 a 3D-view of an inventive drive shaft,

FIG. 13 a 3D-crossectional view of a mounted axial distance setting device

### DETAILED DESCRIPTION OF THE INVENTION

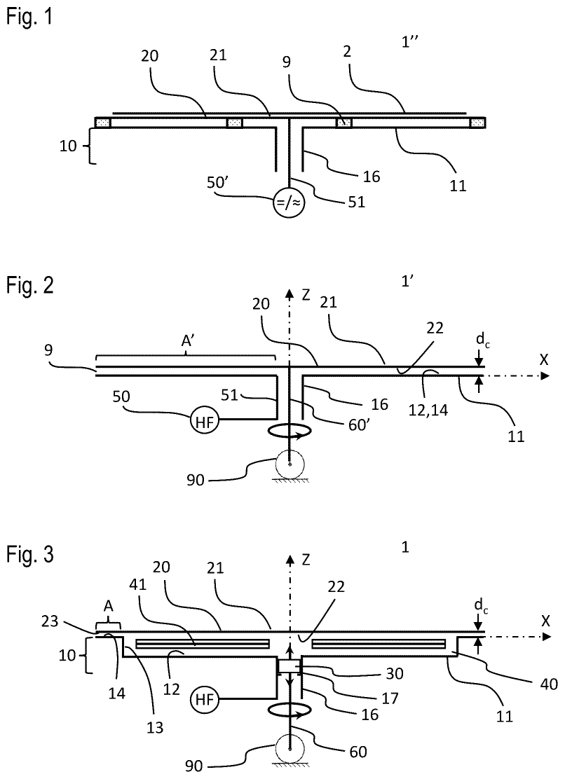

FIG. 1 shows a schematic drawing of a wafer holder and treatment arrangement 1″ of the prior art. Such an arrangement is also called chuck or chuck arrangement 1″ and comprises a chuck base 10, which forms or has a pedestal 16 and a base plate 11, and a wafer carrier plate 20 with a wafer carrying surface 21 to support a wafer 2. A bias supply 50′ to deliver any kind of bias via bias line 51, which may be useful to operate different vacuum treatment processes like etching or layer deposition. The chuck 1′ in FIG. 1 is a static chuck where the chuck base 10 and carrier plate 20 are electrically isolated against each other by respective insulating elements 9.

Contrary to FIG. 1, prior art chuck 1′ as shown in FIG. 2 has a rotating wafer carrier plate 20 mounted to a rotating drive shaft 60′ powered by drive 90, e.g., to optimise a layer thickness distribution during a deposition process. Furthermore the bias supply is a high-frequency (HF) supply 50. As the use of HF-power needs some special care to conduct power uniformly to the whole wafer carrying surface 21, as HF-power is essentially provided via the surface of the respective conductor only, a mere central supply as shown in FIG. 1 might be difficult and could be further hampered by the rotating drive shaft 60′. Therefore, with FIG. 2 an inductive coupling of HF-power from a base plate 12 of the chuck base 10 via the capacitive gap 9 to the wafer carrying plate 20 is provided. In this case the capacitive gap 9 is formed between an annular surface 14, which in this case comprises the whole planar surface 12 of the base plate 10, and the respective surface 22 facing the wafer carrier plate 20 in the whole area A′ of overlapping surfaces. The distance between the 2 capacitive coupling counter faces 14 and 22 defines a critical distance d_{c} as it should be as small as possible to enlarge the capacity of the system, but on the other hand be far enough to avoid the danger of electric shortcuts between the rotating carrier plate and the static base arrangement.

When rotating chucks have to provide further functions like heating and/or cooling, wafer handling/positioning or the like similar problems with a critical distance may arise due to the growing complexity and number of individual parts from which a chuck is assembled, whereby due to summation of individual tolerances mechanical and/or electrical problems as mentioned above may arise.

FIG. 3 shows a respective inventive chuck providing heating elements 41 in a heating compartment 40 commonly defined by the surface 22 of the metal circular wafer carrier plate facing the base arrangement, by an extended, essentially plane surface 12 of the base arrangement 10 and by an inner rim surface 13 encompassing the plane surface 12. Thereby the annular surface 14 extends from the upper end of the inner rim surface 13 in an outward direction with respect to central axis Z. Peripheral area A of overlapping surfaces in FIG. 3 is obviously smaller than area A′ in FIG. 2, which when used as capacitator surface obviously enforces the need for an utmost small gap and critical distance d_{c} to optimize the capacity of the system. Therefore, with the present inventive embodiment as shown in FIG. 3 an axial distance setting device 30 is provided, which is mounted lockable to the drive shaft 60 and rotatably supported by a flange like projection of the pedestal 16 to set a critical distance dc;

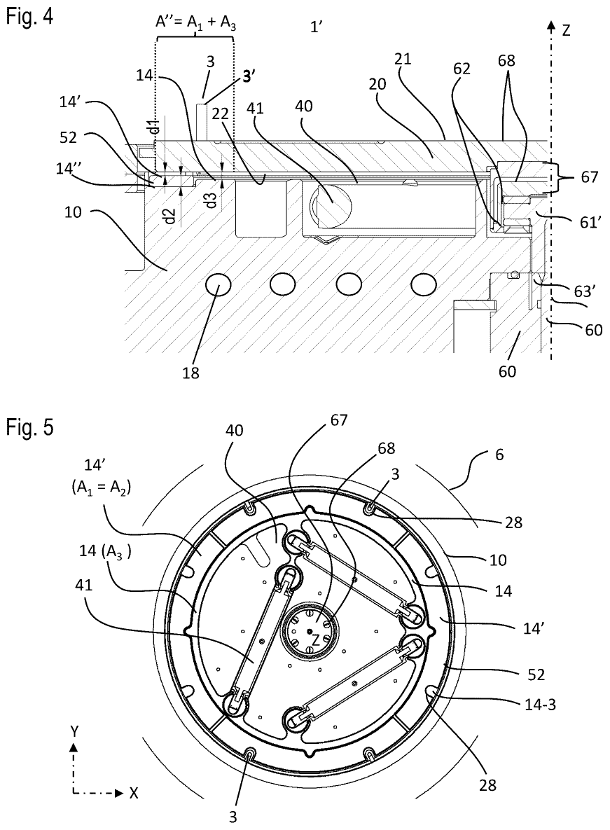

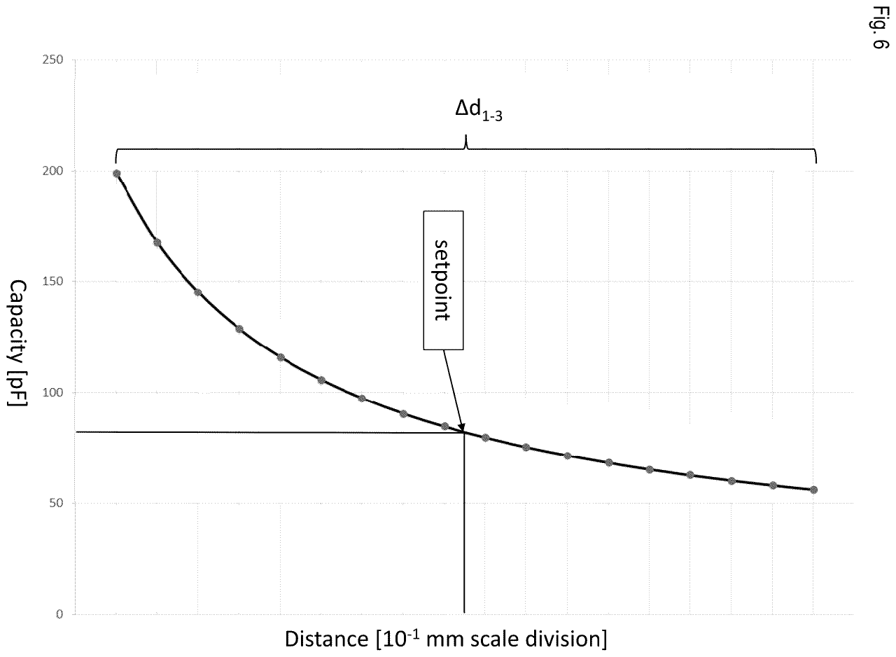

With FIG. 4, a cross section of a capacitively coupled hot chuck arrangement 1′ of the prior art is shown. FIG. 5 shows a top view of a respective base arrangement 10 and heater chamber 40 with heater lamps 40 and wafer pins 3 without the wafer carrier plate 20 of a chuck arrangement 1′ as shown in FIG. 4. In FIG. 4 nominal distances d₁, d₂, d₃ of relevant capacitive gap values are shown contributing to the capacity between surface 22 of the carrier plate 20 and respective counter surfaces 14, 14′ of the base arrangement, and between surface 14′ and the bottom surface 14″ of the recess which equals about to the bottom surface of the insulator 52 in place. The smallest distance d₁ of the gap between the top surface 14′ of insulator 52 and surface 22, which here is the critical capacitive distance de, a “gap” distance at d₂ between two opposing sides of the insulator 52 (which equals to the thickness of the insulator in an axial direction and will be used for calculating the capacity in the following), and a distance d₃ referring to a further capacitive gap with nominal distance d₃>d₂ between surface 14 and 22. According to the resulting tolerances Δd₁ and Δd₂ of the respective gap thickness d₁ and d₃, respectively due to the tolerance Δd₂ of the insulator thickness d₂, as listed together in the calculation below, the tolerance of the critical gap distance results with the chuck as assembled to d₁±0.85 mm, where d₁ is in the range of a few millimeters or even smaller. Due to that high variation with reference to the nominal gap value isolators 52 have been provided in a recess of the annular surface 14 in an outward direction from the center defined by axis Z to safely avoid electrical shortcuts. Insulators 52 are projecting from the annular surface 14 for about one millimeter. Therefore, in this case surfaces 14 and 14′ form the capacitive counter surfaces of the respective annular area A″ of surface 22 as shown in FIG. 4. Surface 14″ on the other hand forms the counter surface of the second surface 14′ of the insulator, which too has to be taken into account as shown in the calculation below. The three nominal distances d₁, d₂, d₃, including the thickness d₂ of the insulator 52, and respective nominal surface areas A₁, A₂, A₃ of essentially annular surfaces 14′, 14″, and 14, defining the respective geometry and nominal gap values as mentioned above are shown in FIGS. 4 and 5. Calculation details are shown in the following:

$${ε}_{RVakuum} = 1 \\ {ε}_{RAl 2 O 3} = 9 \\ {ε}_{0} = 8.85 * 1 {0}^{- 12} \frac{As}{Vm} \\ {A}_{1} = {A}_{2} \\ {A}_{3} \\ {d}_{1} \pm 0.85 \\ {d}_{2} \pm 0.1 \\ {d}_{3} \pm 0.75 \\ {C}_{1} = ( {ε}_{0} * {ε}_{RVakuum} ) * \frac{{A}_{1}}{{d}_{1}} \\ {C}_{2} = ( {ε}_{0} * {ε}_{RAl 2 O 3} ) * \frac{{A}_{2}}{{d}_{2}} \\ {C}_{3} = ( {ε}_{0} * {ε}_{RVakuum} ) * \frac{{A}_{3}}{{d}_{3}} \\ {C}_{tot} = ( \frac{1}{\frac{1}{{C}_{1}} + \frac{1}{{C}_{2}}} ) + {C}_{3}$$

As can be seen from the calculation C₁ refers to the capacity of the gap between surface 14′ and surface 22, C₂ refers to the capacity of isolator thickness between the bottom surface 14″ of the recess and surface 14′ of the isolator 52. C₁ and C₂ are serial capacities which are in parallel to capacity C₃ referring to the gap defined by surface 14 and the respective annular counter surface area of surface 22. Therefore, the value of the total capacity Cₜₒₜ hereby may vary about the factor 4, due to given dimensional variations, which obviously is not very satisfying. An exemplary capacity versus gap distance d diagram of a respective state of the art chuck, can be seen in FIG. 6, showing a scattering of the capacity range of about 150 pF due to the total systemic geometric tolerance of Δd₁₋₃=+0.85 mm=1.7 mm, where the three distances d₁₋₃ as well as respective surface areas A₁₋₃ contribute to the overall deviation, as explained above.

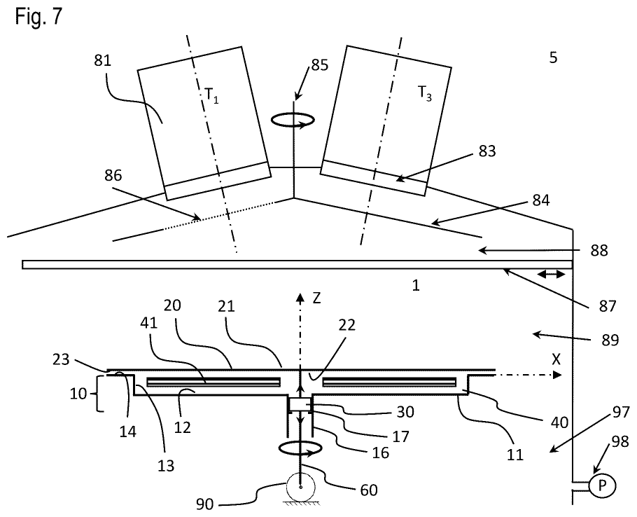

FIG. 7 shows a schematic drawing of a vacuum treatment apparatus, comprising an inventive wafer holder or chuck as explained with FIG. 3. The vacuum treatment apparatus 5 is equipped with four magnetron sputter stations 81, each comprising a target 83. Target axes T₁ to T₄ are directed towards the wafer carrier plate 20 oblique and here symmetrically towards axis Z. A spherical target shutter 84 with a target opening 86 is mounted centrally, i.e. in axis Z, and rotatable on a driven shutter shaft 85 in the system cover, directly in front of the targets 83 to provide a free line of sight between the target in operation and a wafer to be coated with the respective target material. Furthermore, a planar process shutter 87 is provided to close the dome area 88 completely against the processing space 89.

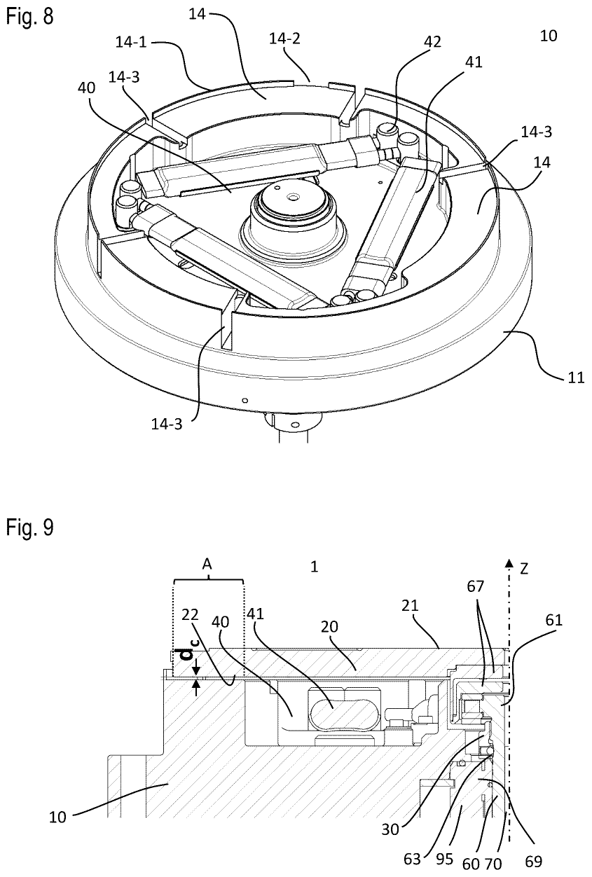

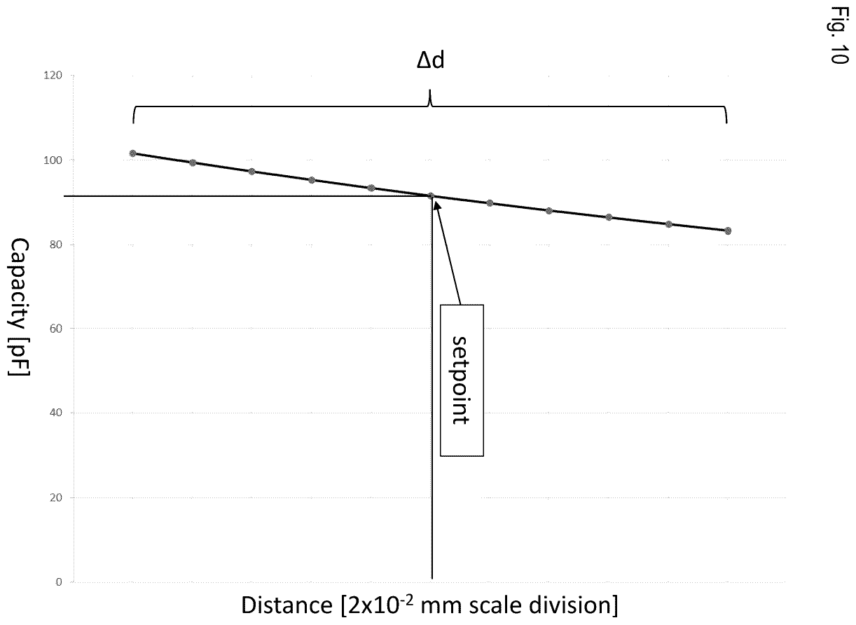

In the following further details and examples of inventive embodiments of the wafer holder are explained. FIG. 8 and FIG. 9 referring to an embodiment comprising a heater compartment 40, which is also suitable for high temperature applications. A 3D-top view of a base arrangement 10 with an open heater compartment 40 is shown in FIG. 8. A circumferential heat reflector 14-1 protrudes the outer diameter of the annular surface 14 in an z-direction, being interrupted by a measuring cut-out 14-2 provided to measure the critical distance d_{c} between annular surface 14 and surface 22 of the wafer carrier plate 20 facing the base arrangement when mounted (see FIG. 9). Measurements can be performed as an example in a simple way with a calliper rule. Recesses 14-3 are provided to receive wafer support pins 3 (see FIG. 5) to lift and lower a wafer from or towards the (upper) wafer carrying surface 21 of the wafer carrier plate 20 and correspond with respective cut-outs 28 in the wafer carrier plate (see also FIG. 5).

Similar to FIG. 4 of the prior art, with FIG. 9 the critical distance d_{c} is shown, which in the case of FIG. 4 would be d₁. However, in the present inventive embodiment, due to the use of a distance setting device 30, there is no need to use insulators 52 to avoid electric short-cuts between base arrangement and wafer carrier plate, and no need to provide two capacitive gaps as shown with the chuck in FIG. 4. With the embodiment as shown in FIG. 9 the critical distance between surfaces 14 and 22 could be set to d_{c}±0.1 mm, or Δd=±0.1 mm=0.2 mm, as shown in FIG. 10. Respective variations of the capacity C of the inventive chuck can thereby be set in a close range of ΔC=+/−10 pF. Thereby it could be shown that not only the positioning precision but also the capacitive change per unit of length could be diminished by using a design having essentially only one capacitive effective gap of uniform thickness d, respectively d_{c}. Also calculation details are simplified as shown in the following, as essentially there is only one relevant gap distance to consider which is the critical gap distance d_{c} referring to the distance between annular surface 14 and the respective facing area of the surface 22 facing the base arrangement:

$${ε}_{RVakuum} = 1 \\ {ε}_{0} = 8.85 * 1 {0}^{- 12} \frac{As}{Vm} \\ A \\ d = {d}_{c} \\ C = ( {ε}_{0} * {ε}_{RVakuum} ) * \frac{A}{{d}_{c}}$$

Due to the distance setting device 30 as described above and will be further detailed at the hand of an example below, the distance d_{c} can be corrected in 10 equidistant steps of 0.1 mm when a respective mismatch should be measured via a measuring cut-out 14-2 of heat-reflector 14-1, see FIG. 8, in an assembled state of a chuck 1 loaded with the weight of a weight ring or a respective dummy weight to cancel the backlash of a dynamic vacuum seal 69, here a ferrofluidic seal arrangement.

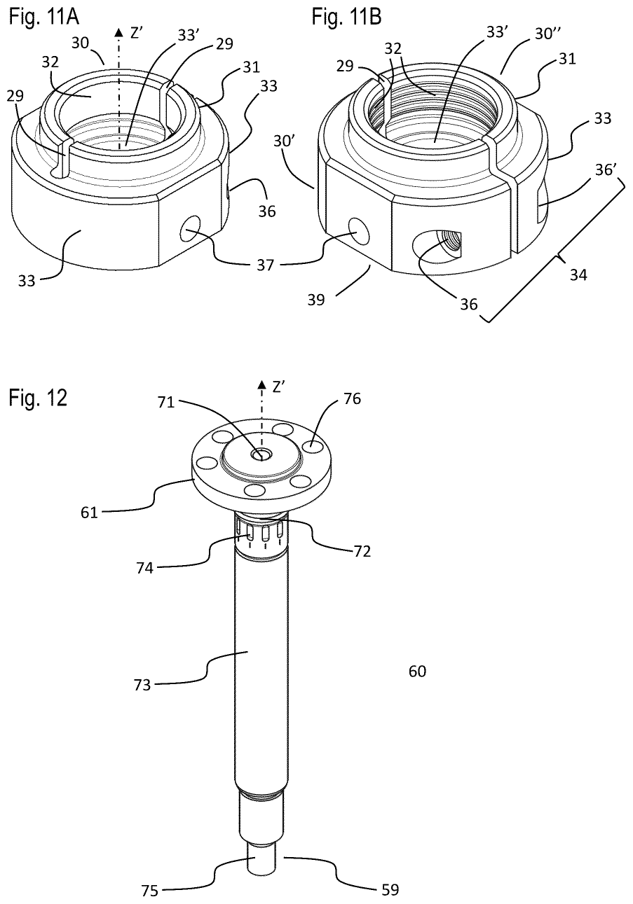

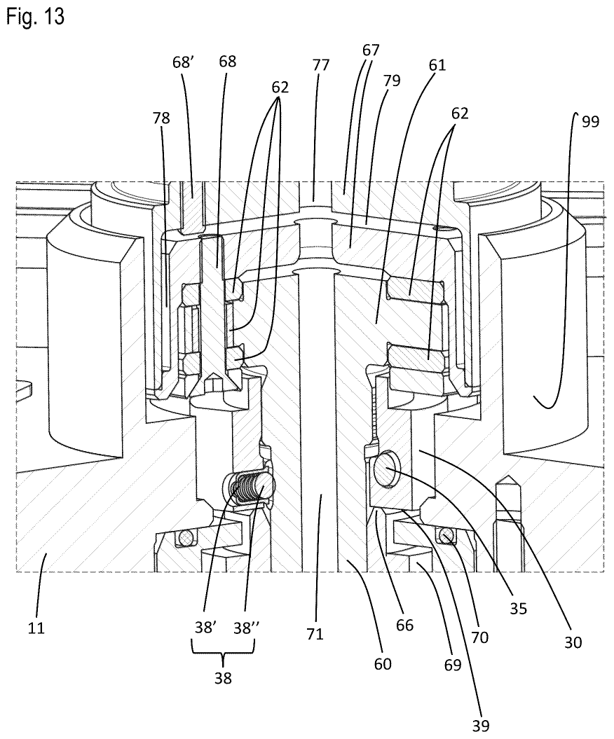

FIG. 11A shows a 3D-view of an inventive distance setting device 30 comprising a slotted hollow body 30, preferably made from a bearing alloy or coated with a dry gliding layer on the lower face 39 of the body 30. The slotted hollow body 30 is designed with an internal fine thread 32, details see FIG. 11B, in the area of the thread coupler 31 and a thread-free counterbore area 33′ within the counterbore sleeve 33. A spring 38′ and snap-in ball 38″ assembly 38 (see also FIG. 13) is provided in a radial bore 37 of the counterbore sleeve 33 of the body 30 with an opening towards the center of the body, respectively towards axis Z′ when mounted to shaft 60. A retaining rim (not shown) may be provided at the inner circumference of the bore where it meets the counterbore diameter to allow only a part of the ball be forced out of the inner opening of the bore 37. A locking thread 36 is provided at one side of the slot 92 in the counterbore sleeve 33 of the body 30 and a respective locking screw mount 36′ on the other side of the slot 92, both essentially in parallel to a tangent of the fine thread diameter (see also FIG. 11B) and aligned to each other, to lock the slotted hollow body 30 in the desired position with the help of a locking screw 35. The slotted hollow body 30 can thereby be fixed on the drive shaft 60 with locking mechanism 34 comprising respective locking screw 35, locking thread 36, and screw mount 36′ (see also FIG. 13). The fine thread 32 of the distance setting device 30 is designed to cooperate with a counter fine thread 72, here provided immediately below the head 61 of drive shaft 60 as shown in FIG. 12.

FIG. 11B shows a 3D-view of an alternative distance setting device 30 comprising a two-part hollow body 30′, 30″ preferably made from a bearing alloy or coated with a dry gliding layer on the lower face 39 of body 30′ and 30″. The two-piece hollow body 30′, 30″ is designed similar to the slotted body 30 of FIG. 11A with an internal fine thread 32 in the area of the thread coupler 31 and a thread-free counterbore area 33′ within the counterbore sleeve 33 and a respective radial bore 37 in the counterbore sleeve 33 of one body 30′. A locking thread 36 is provided in the counterbore sleeve 33 of the one body 30′ and a respective locking screw mount 36′ in the other body 30″, both in parallel to a tangent of the fine thread diameter, to lock first lateral ends of bodies 30′, 30″. On the opposite side of the slot 92, which here divides the half-nut bodies 30′, 30″ completely from each other a corresponding screw connection or preferably a hinge (not shown) may be provided to hold the second lateral ends together.

The drive shaft 60 further comprises a coupling piece 75 provided on the end opposite to the head end to connect to drive 90, e.g. direct or by a power train (not shown). Further on a sealing surface 73 is provided on a diameter of the drive shaft 60 allowing a rotational movement when mounted and an axial-parallel linear movement to mount the shaft in the dynamic vacuum seal 69. On a further diameter of the drive shaft 60 adjacent to the counter thread 72, elongated and axially directed groves 74 are provided to cooperate with the ball 38″ of the snap-in ball assembly 38 at the inner diameter of the counterbore 33. When the ball has snapped in one grove 74 after the distance setting device 30 has been screwed on the counter thread to provide a nominal distance of d_{c}, the lock screw 70 can be tightened to lock the position of the distance setting device and therewith set the nominal position which is shown in further details with FIG. 13 showing a 3D-crossectional view of an inventive axial distance setting device 30 build in a baseplate 11 of a respective chuck 1. The baseplate 11 is provided with a protective wall 99 to further shield the drive head 61 in addition to the heat protecting function of the double-walled sleeve-cup 67, the latter providing an opening 79 from gas passthrough 77 to interspace 78 between the respective double walls of the sleeve-cup. With screws 68 and isolators 62 the double-walled sleeve-cup 67 is mounted electrically isolated on the drive shaft head 61. The wafer carrier plate 20 is then mounted centrally on top of the double-walled sleeve-cup 67 by means of screws 68′. The gliding surface on the lower face 39 of the body of the distance setting device 30 sits on a nose 66 of the housing 95 of the dynamic seal configuration 69 as shown in FIG. 13.

An inventive rotary drive shaft and vacuum feedthrough may consist of an axial distance setting device 30 and a drive shaft 60 alone as exemplified in FIGS. 11A, 11B and 12, whereat FIG. 13 shows a respective mounting ensemble for high temperature applications and electrically isolation of a capacitive coupled RF chuck.

### REFERENCE SIGNS LIST

1 chuck arrangement
2 wafer
3 wafer support (e.g. pin-like, pin-like with a radially elongated effector head, or ring-like)
3′ wafer support surface
5 vacuum treatment apparatus
6 chamber wall
7 gas feed line
8 gas reservoir
9 capacitive gap
10 base arrangement
11 base plate
11′ sub-baseplate
12 plane surface
13 circular protruding rim surface
14 annular surface
14′ second annular surface
14-1 heat reflector
14-2 measuring cut-out
14-3 recess corresponding with cut-out 28
15 rim
16, 16′ pedestal
17 flange or a projection in the pedestal
20, 20′ wafer carrier plate
21 wafer carrying surface
22 surface facing the base arrangement
23 surface facing the annular surface
28 cut-out in wafer carrier plate
29 slot
30 distance setting device
31 thread coupler
32 fine thread
33 counterbore sleeve
33′ counterbore (area)
34 locking mechanism
35 locking screw
36 locking thread
37 radial bore
38 snap-in ball assembly
38′ spring
38″ ball
39 lower face of the body
40 heater compartment
41 heat lamp tube
42 electrical connection (lamp tube)
50, 50′ bias supply
51 bias line
52 electric insulator
59 shaft foot
60 drive shaft
61 drive shaft head
61′ drive shaft head (prior art)
62 electric insulator
63 slide bearing level
63′ slide bearing level (prior art)
64 slide surface of the drive shaft
65 slide surface of the base arrangement
66 slide nose
67 double-walled sleeve-cup
68 screw
69 dynamic vacuum seal
70 vacuum seal
71 gas feedthrough (drive shaft)
72 counter thread
73 sealing surface
74 elongated, axially directed groves
75 coupling area
76 mounting holes
77 passthrough
78 interspace
79 opening
81 magnetron
83 target
84 rotating target shutter
85 shutter shaft
86 target opening
87 process shutter
88 dome area
89 processing space
90 drive
95 housing of ferrofluidic vacuum seal
97 pumping compartment
98 pump
99 protective wall
A, A₁, A₂, A₃ annular plane surfaces
T₁, T₃ target axes
X, Y planar axes
Z/Z′ vertical and central (rotational) axis (wafer carrier plate/shaft, body)

1. A wafer holder and treatment arrangement to be mounted to a vacuum wafer treatment chamber, comprising
a base arrangement having an annular surface;
a drive shaft centered with respect to said annular surface:
a wafer carrier plate mounted on the drive shaft and having a surface facing the annular surface in parallel, wherein said drive shaft and the wafer carrier plate are rotatable about a rotational axis Z centered with respect to said annular surface relative to and supported by said base arrangement;
a dynamic vacuum seal configuration operatively connected to the drive shaft;
a distance setting device mounted lockable to the drive shaft and configured to be supported rotatable by an element of said base arrangement or in or on a bottom of a treatment chamber to set a critical distance d_{c};
wherein said critical distance d_{c} is defined as a distance in a direction parallel to the rotational axis Z between said annular surface of said base arrangement and said surface of the wafer carrier plate.

2. The wafer holder and treatment arrangement of claim 1, wherein the base arrangement further comprises an essentially plane surface circumferentially bordered by a rim protruding towards the wafer carrier plate and comprising said annular surface.

3. (canceled)

4. The wafer holder and treatment arrangement of claim 1, comprising a wafer retaining arrangement operationally coupled to said wafer carrier plate.

5. The wafer holder and treatment arrangement of claim 1, comprising at least three wafer supports mounted to the base arrangement and configured to be extended out of said annular surface and retracted into said annular surface.

6. The wafer holder and treatment arrangement of claim 1, wherein the drive shaft has a sealing surface, said base arrangement comprises a bottom plate comprising said annular surface and said dynamic vacuum seal configuration, said dynamic vacuum seal configuration encompasses the sealing surface, and the distance setting device is supported rotatable by an element of said bottom plate or an element of said dynamic vacuum seal configuration.

7. The wafer holder and treatment arrangement of claim 1, wherein the drive shaft comprises an external thread and the distance setting device comprises a longitudinally slotted or longitudinally divided hollow body having a gliding surface and an internal thread engaged with the external thread of said drive shaft, and a locking mechanism to clamp or lock the hollow body on the external thread of the drive shaft.

8. The wafer holder and treatment arrangement of claim 7, wherein the locking mechanism comprises at least one threaded connection between two slot sides of the hollow body outside a diameter of the internal thread and parallel to a tangent of the internal thread.

9. The wafer holder and treatment arrangement of claim 7, wherein the drive shaft comprises a plurality of grooves provided on an outer circumference of the drive shaft, and wherein the slotted hollow body forms a nut comprising said internal thread, a thread-free counterbore area, a radial bore having an opening towards the rotational axis Z in said thread-free counterbore area, and a spring and snap-in ball assembly provided in the radial bore to interact with the grooves.

10. The wafer holder and treatment arrangement of claim 1, wherein said wafer carrier plate is electrically isolated from said base arrangement and configured to be electrically connected or capacitively coupled to an electric biasing source.

11. The wafer holder and treatment arrangement of claim 1, comprising an electric isolator arranged between said drive shaft and said wafer carrier plate, and wherein said surface of the wafer carrier plate has a peripheral surface area arranged in parallel with a part of the annular surface, said peripheral surface area and said part of the annular surface both forming together an essentially circumferential planar capacitor with a defined capacitive gap of said critical distance d_{c}.

12. The wafer holder and treatment arrangement of claim 1, wherein the wafer carrier plate has a wafer carrying surface, and wherein the wafer holder and treatment arrangement comprises a gas outlet- and dispensing-arrangement through and along said wafer carrying surface.

13.-16. (canceled)

17. The wafer holder and treatment arrangement of claim 4, wherein said wafer retaining arrangement has a weight-ring dimensioned so as to reside on a periphery of a wafer.

18. A vacuum treatment apparatus comprising a wafer holder and treatment arrangement according to claim 1, further comprising a vacuum pumping arrangement, a target and a target shutter configured to separate said target from a process space between said target and said wafer carrier plate.

19. The vacuum treatment apparatus of claim 18, comprising at least two targets each having a respective target shutter configured to separate a respective target from said process space, and optionally comprising one single process shutter configured to separate all of the at least two targets at once from said process space.

20. A method of setting a critical distance d_{c} between a base arrangement and a wafer carrier plate mounted on a drive shaft,
the method comprising:
determining an average distance d_{cA} by measuring an actual critical distance d_{c} several times in different positions of the wafer carrier plate in relation to the base arrangement, calculating a mean value thereof, and setting the average distance d_{cA} to be equal to the mean value;
comparing the average distance d_{cA} to a nominal distance d_{cN}, and in case of a difference between the average distance d_{cA} and the nominal distance d_{cN} surmounting a predetermined differential step:
demounting said drive shaft together with said wafer carrier plate and said distance setting device from the base arrangement;
adjusting the critical distance d_{c} by said distance setting device to the nominal distance d_{cN} in a demounted state of the drive shaft and the wafer carrier plate and locking the distance setting device on the drive shaft;
mounting said drive shaft together with said wafer carrier plate and said distance setting device to the base arrangement.

21. The method of claim 20, comprising setting a weight-ring or a dummy weight on the wafer carrier plate during determining the average distance d_{cA}.

22. A rotary drive shaft and vacuum feedthrough having a drive shaft and a distance setting device, the drive shaft comprising
a shaft head and a shaft foot, wherein the shaft head is configured to mount a wafer carrier plate on the shaft head;
a power coupling area at or near the shaft foot;
an elongated sealing surface on an outer circumference of the drive shaft;
wherein the distance setting device and is mounted lockable to the drive shaft and has a gliding surface to support the distance setting device and the drive shaft when the distance setting device is locked to the drive shaft.

23. The rotary drive shaft and vacuum feedthrough of claim 22, wherein the drive shaft has an external thread and the distance setting device has an internal thread in engagement with the external thread of the drive shaft.

24. The rotary drive shaft and vacuum feedthrough of claim 22, wherein the distance setting device has a locking mechanism that locks the distance setting device to the drive shaft.

25. (canceled)

26. The method of claim 20, wherein
said base arrangement comprises an annular surface perpendicular to a rotational axis Z centered with respect to said annular surface;
said wafer carrier plate comprises a surface facing the annular surface in parallel;
said critical distance d_{c} is defined as a distance in a direction parallel to the rotational axis Z, between said annular surface of said base arrangement and said surface of the wafer carrier plate;
said drive shaft and the wafer carrier plate are rotatable about the rotational axis Z relative to said base arrangement;
said distance setting device is configured to be supported rotatable by an element of said base arrangement, by a housing of a dynamic vacuum seal configuration, or in or on a bottom of a treatment chamber.
